(19) United States
(12) Patent Application Publication
(10) Pub. No.: US 2024/0318342 A1
(43) Pub. Date: Sep. 26, 2024

(54) COMPOSITIONS AND METHODS FOR THE ELETRODEPOSITION OF NANOTWINNED COPPER

(71) Applicant: MacDermid Enthone Inc., Waterbury, CT (US)

(72) Inventors: Jianwen Han, Southbury, CT (US); Pingping Ye, Bethany, CT (US); Kyle M Whitten, Cheshire, CT (US); Stephan I. Braye, West Haven, CT (US); Thomas B. Richardson, Killingworth, CT (US); Elie H. Najjar, Norwood, MA (US)

(21) Appl. No.: 18/578,049

(22) PCT Filed: Jul. 25, 2022
(86) PCT No.: PCT/US22/38133

§ 371 Date: Jan. 10, 2024

Related U.S. Application Data
(60) Provisional application No. 63/229,792, filed on Aug. 5, 2021.

(51) Int. Cl. C25D 3/38; C25D 5/00; C25D 7/12; C30B 7/12; C30B 29/02; C30B 29/60

(52) U.S. Cl. CPC C25D 3/38; C25D 5/617; C25D 7/12; C30B 7/12; C30B 29/02; C30B 29/605

(57) ABSTRACT

A copper electrolyte comprising a copper salt, a source of halide ions, and a linear or branched polyhydroxyl. The copper electrolyte is used to deposit copper having a high density of nanotwinned columnar copper grains on a substrate. The linear or branched polyhydroxy] may comprise a reaction product between 2,3-epoxy-1-propanol and an amine compound. A leveler comprising a polymeric quaternary nitrogen species and/or an accelerator comprising an organic sulfur compound may also be added to the copper electrolyte so long as the nanotwinned columnar copper grains are maintained.

### FIELD OF THE INVENTION

The present invention generally relates to the electrodeposition of nanotwinned copper and electrolytic copper plating baths for producing nanotwinned copper deposits.

### BACKGROUND OF THE INVENTION

Electrochemical deposition processes are well-established in integrated circuit fabrication processes. Copper lines can be formed by electroplating the metal into very thin, high-aspect-ratio trenches and vias in a methodology commonly referred to as “damascene” processing (pre-passivation metallization).

With the advancement of microelectronics there is a continual need to create smaller and denser interconnect features. Copper is one of the most essential conductors in microelectronic devices due to high ductility and conductivity. One method towards this goal is the removal of solder between two separate substrates that connect copper vias, pads, bumps, or pillars, which can be replaced by, for example, Cu—Cu hybrid bonding.

To ensure the success of this method, which requires both high temperature and high pressure, it is greatly preferred to generate electroplated copper in (111) orientation with >90% nanotwinned columnar copper (nt-Cu) grains. While not being held to a particular theory, it is believed that when the two nt-Cu substrates come into contact and are exposed to high temperatures and pressures, the nt-Cu growth will extend between the boundaries of the copper substrates forming a Cu—Cu bond that extends across the interface.

Due to the combination of excellent mechanical properties, good conductivity, and unique structure, nanotwinned copper has drawn attention for use in microelectronics. The mechanical strength of metals such as copper generally increases when the size of the crystal grain is reduced to a nanoscale level. Nanotwinned copper represents ultrafine-grain copper whose grains contain a high density of layered nanoscopic twins divided by coherent twin boundaries. By introducing nanoscale twins into the microstructure of copper, properties including mechanical strength, ductility, electromigration resistivity, and hardness can be improved.

Nanoscale levels of thin metal films can have exemplary mechanical properties. As a result, metals that have nanotwin crystalline properties may be suitable for applications such as through silicon vias (TSV), semiconductor chip interconnect, packaging substrate pin through hole, metal interconnect (for example, copper interconnect), or metal materials on substrate.

Nanotwinned copper can be achieved in several ways, including, for example, by sputtering and by electrolytic deposition using a copper electroplating composition that has been optimized to produce nanotwinned copper. One of the advantages of sputtering is the high purity in the copper film, with the ability to contour the preferred orientation of grains. Sputtered (111)-oriented nanotwinned copper has been shown to have high thermal stability and strength.

On the other hand, direct current electrolytic plating has the advantage of being extremely compatible with industrial mass production. Electroplated nanotwinned copper can be classified into two groups—equiaxial grain nanotwinned copper and (111)-oriented nanotwinned copper.

Crystal defects can influence mechanical, electrical, and optical properties of a material. Twinning occurs in a material where two parts of a crystal structure are symmetrically related to one another. In a face-centered cubic (FCC) crystal structure, of which copper is included, coherent twin boundaries can be formed as (111) mirror planes from which the typical stacking sequence of (111) planes is reversed. In other words, adjacent grains are mirrored across coherent twin boundaries in a layered (111)-structure, Twins grow in a layer-by-layer manner extending along a lateral (111) crystal plane where a twin thickness is on the order of nanometers, hence the name “nanotwins.” Nanotwinned copper (nt-Cu) exhibits excellent mechanical and electrical properties and can be used in a wide variety of applications in wafer-level packaging and advanced packaging designs.

Compared to copper exhibiting conventional grain boundaries, nanotwinned copper possesses strong mechanical properties, including high strength and high tensile ductility. For example, nanotwinned copper demonstrates high electrical conductivity, which may be attributable to the twin boundary, causing electron scattering that is less significant compared to a grain boundary. Nanotwinned copper also exhibits high thermal stability, which may be attributable to the twin boundary having excess energy on the order of magnitude lower than that of a grain boundary and enables high copper atom diffusivity, which is useful for copper-to-copper direct bonding. In addition, nanotwinned copper shows high resistance to electromigration, which may be a result of twin boundaries slowing down electromigration-induced atomic diffusion. Nanotwinned copper demonstrates a strong resistance to seed etch that may be important in fine-line redistribution layer applications and also shows low impurity incorporation, which results in fewer Kirkendall voids as a result of soldered reactions with the nanotwinned copper.

In some aspects, nanotwinned copper enables direct copper-copper bonding, which may occur at low temperatures, moderate pressures, and lower bonding forces/times. Typically, the deposition of copper structures results in rough surfaces, and in some instances, prior to copper-copper bonding, electrodeposition of nanotwinned copper may be followed by electropolishing to achieve smooth surfaces. With the smooth surfaces, the nanotwinned copper structure may be used in copper-copper bonding with shorter bonding times, lower temperatures, and fewer voids.

U.S. Pat. No. 7,074,315 to Desmaison et al., the subject matter of which is herein incorporated by reference in its entirety, describes a copper electrolyte for depositing a matte layer of copper. The electrolytic copper plating bath comprises at least one polyhydroxyl compound selected from poly(1,2,3-propanetriol), poly(2,3-epoxy-1-propanol), and derivatives thereof to produce copper deposits that are matte and show a uniform, slight roughness to provide, without additional pretreatment, a sufficient bond of organic coatings. However, there is no suggestion regarding the use of the copper electrolyte for depositing nanotwinned copper.

WO2020/092244 to Banik et al, the subject matter of which is herein incorporated by reference in its entirety, describes a copper structure having a high density of nanotwinned copper deposited on a substrate. Banik does not describe any particular electrolytic copper plating bath but instead describes electroplating conditions, including applying a pulsed current waveform that alternates between constant current and no current, where the duration of no current being applied is substantially greater than a duration of a constant current being applied.

U.S. Pat. No. 10,566,314 to Yang, the subject matter of which is herein incorporated by reference in its entirety, describes how the optimal copper grain structure for Cu—Cu metal to metal bonding is columnar grain microstructure. The copper grain microstructure plated by the disclosed suppressor-only system produces a columnar grain structure as a result of plating nanotwinned copper. In addition, while columnar grains are mentioned, there is no mention of (111) copper grain structure of nanotwinning copper.

Research has shown that very few materials are able to produce nanotwinned copper (nt-Cu) or a copper deposit that exhibits a high degree of nanotwinning. One such material is poly(2,3-epoxy-1-propanol), which is a linear or branched polyhydroxyl with a molecular weight of about 200 to about 20,000, more preferably about 500 to about 5,000, even more preferably about 1,000 to about 3,000.

It has also been believed that the introduction of other organic electroplating compounds will disrupt the ability of the polyhydroxyl material to produce nt-Cu. These prohibitive compounds can include accelerators, brighteners, carriers, wetters, and/or levelers.

In addition, copper to copper hybrid bonding requires nanotwinned copper microstructure. Typically, nanotwinned copper can only be plated conformally, which limits the use of the plating solution to applications that are only conductive on the base layer. Structures where the bottom and sidewalls are conductive, such as vias, have been a limitation.

There remains a need in the art for an improved electrolytic copper solution for producing nanotwinned copper deposits, especially for an electronic copper solution that is capable of producing nanotwinned copper in features of a microelectronic substrate. In addition, there remains a need in the art for an improved electrolytic copper solution that can deposit nanotwinned copper in (111) orientation in features of the microelectronic substrate with a high density and/or high percentage of nanotwinning.

### SUMMARY OF THE INVENTION

It is an object of the present invention to provide an improved copper electroplating solution.

It is another object of the present invention to provide a copper electroplating solution that is capable of producing nanotwinned copper in the deposit.

It is another object of the present invention to provide a copper electroplating solution that is optimized to deposit nanotwinned copper in features of a microelectronic substrate.

It is still another object of the present invention to provide a copper electroplating solution that is capable of filling high aspect ratio vias with nanotwinned copper grain growth from the bottom of the vias.

It is still another object of the present invention to provide nanotwinned copper in features of a microelectronic substrate in a (111) orientation.

It is still another object of the present invention to provide a copper electroplating solution that is capable of depositing nanotwinned copper in a via structure where the bottom, sidewalls and top field comprise conductive copper.

It is yet another object of the present invention to provide a copper deposit in features of a microelectronic substrate that exhibits a high density of nanotwinning.

To that end, in one embodiment, the present invention generally relates to a copper electrolyte, wherein the copper electroplating solution comprises:
a) a copper salt;
b) a source of halide ions; and
c) a suppressor, wherein the suppressor comprises a linear or branched polyhydroxyl,
   wherein the copper electrolyte also comprises one or more of:
   (i) an accelerator, wherein the accelerator comprises an organic sulfur compound; and
   (ii) a leveler, wherein the leveler comprises a polymeric quaternary nitrogen species;
   wherein the copper electrolyte is configured to deposit nanotwinned copper on a substrate.

In another embodiment, the present invention also relates generally to a method of using the copper electroplating solution described herein to produce a copper deposit on a substrate that exhibits a high density of nanotwinning.

### BRIEF DESCRIPTION OF THE FIGURES

FIG. 1 depicts an SEM (20 μm width at 15K magnification) of a copper deposit produced in accordance with Example 1.

FIG. 2 depicts an SEM (20 μm width at 15K magnification) of a copper deposit produced in accordance with Example 2.

FIG. 3 depicts an SEM (20 μm width at 15K magnification) of a copper deposit produced in accordance with Example 3.

FIG. 4 depicts an SEM (20 μm width at 15K magnification) of a copper deposit produced in accordance with Example 4.

FIGS. 5A and 5B depicts SEMs (20 μm width at 15K magnification) of copper deposits produced in accordance with Comparative Example 5.

FIGS. 6A, 6B, and 6C depict an SEMs (20 μm width at 15K magnification) of copper deposits produced in accordance with Comparative Example 6.

FIG. 7A depicts an SEM (15 μm width at 20K magnification) of a copper deposit showing plated nanotwinned copper on a blanket surface. FIG. 7B depicts an SEM (15 μm width at 20K magnification) of a copper deposit on a blanket surface in which the nanotwinned copper microstructure is lost.

FIG. 8A depicts an SEM (15 μm width at 20K magnification) of a copper deposit showing plated nanotwinned copper on a blanket surface. FIG. 8B depicts an SEM (15 μm width at 20K magnification) of a copper deposit on a blanket surface in which the nanotwinned copper microstructure is lost.

FIG. 9 depicts an SEM (15 μm width at 20K magnification) of a copper deposit showing plated nanotwinned copper on a blanket surface.

FIG. 10A depicts an SEM (15 μm width at 20K magnification) of copper viafilling on a damascene like structure with a one bath process. FIG. 10B depicts an SEM (15 μm width at 20K magnification) of copper viafilling on a damascene like structure with a two bath process (nt-Cu bath followed by via filling bath).

FIG. 11 depicts the XRD analysis of a nt-Cu film, plated with an electrolyte containing only a suppressor, that has a high concentration of Cu (111) microstructure.

FIG. 12 depicts an EBSD analysis of a nt-Cu film, plated with an electrolyte containing only a suppressor, that shows that the nt-Cu is (111) preferred oriented, and a majority of the copper grains are smaller than 1.0 μm.

### DETAILED DESCRIPTION OF THE PREFERRED EMBODIMENTS

The inventors of the present invention have discovered that electrodeposition of high density of nanotwin copper in (111) orientation can enable smaller and denser interconnect features between two separate substrates used to connect copper vias, pads, bumps, pillars, etc. via Cu—Cu hybrid bonding.

Based thereon, the inventors of the present invention have found that certain types of accelerators and levelers can function synergistically with nanotwin producing suppressors without compromising the nanotwinned copper microstructure. This discovery has thus led to the development of a two or three component copper plating system that is capable of superfilling copper in features of a microelectronic substrate while maintaining a vertical growth nanotwinned copper microstructure.

Whether the plated copper structure contains only a conductive surface (such as a redistribution layer (RDL) or a pillar) or a structure with a completely metallized surface (such as a via), it is highly desirable that greater than 90% nt-Cu be observed wherein the boundary from initial copper seed to nt-Cu is 1 μm or less.

Recent advancements include developing a copper electrolyte that is capable of providing a copper deposit having a high density of nanotwinning in the deposit. In one embodiment, the copper electrolyte can be used for super-filling high aspect ratio vias while maintaining a nanotwinned copper microstructure with the use of novel combinations of accelerator, suppressor, and leveler. Such high aspect ratio vias generally have an aspect ratio of 1:4 to 4:1, In addition, the vias may have a diameter within a range of about 1 μm to 20 μm and a depth of about 1 μm to 20 μm. In one embodiment, the copper electrolyte is capable of filling such high aspect ratio vias with nanotwinned copper grain growth extending from the bottom of the vias (i.e., bottom-up filling of nanotwinned copper).

As used herein, “a,” “an,” and “the” refer to both singular and plural referents unless the context clearly dictates otherwise.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform in the invention described herein. Furthermore, it is also to be understood that the value to which the modifier “about” refers is itself specifically disclosed herein.

As used herein, spatially relative terms, such as “beneath,” “below,” “lower,” “above,” “upper” and the like, are used for ease of description to describe one element or feature's relationship to another element(s) or feature(s) as illustrated in the figures. It is further understood that the terms “front” and “back” are not intended to be limiting and are intended to be interchangeable where appropriate.

As used herein, the terms “comprises” and/or “comprising,” specify the presence of stated features, integers, steps, operations, elements, and/or components, but do not preclude the presence or addition of one or more other features, integers, steps, operations, elements, components, and/or groups thereof.

As used herein, the term “substantially free” or “essentially free” if not otherwise defined herein for a particular element or compound means that a given element or compound is not detectable by ordinary analytical means that are well known to those skilled in the art of metal plating for bath analysis. Such methods typically include atomic absorption spectrometry, titration, UV-Vis analysis, secondary ion mass spectrometry, and other commonly available analytically techniques.

As used herein, the term “features” refers to vias, through-silicon vias (TSV), trenches, pillars, pad, bumps, etc. that may be present on a microelectronic substrate.

As used herein, the term “high density” of nanotwinned copper refers to a copper deposit that contains at least 75% or at least 80% or at least 85% or at least 90% or at least 95% of nanotwinned columnar copper grains in the deposit.

All amounts are percent by weight unless otherwise noted. All numerical ranges are inclusive and combinable in any order except where it is logical that such numerical ranges are constrained to add up to 100%.

The terms “plating” and “deposit” or “deposition” are used interchangeably throughout this specification. The terms “composition” and “bath” and “solution” are used interchangeably throughout this specification. The term “alkyl,” unless otherwise described in the specification as having substituent groups, means an organic chemical group composed of only carbon and hydrogen and having a general formula: CₙH₂ₙ₊₁. The term “average” is equivalent to the mean value of a sample. All amounts are percent by weight unless otherwise noted. All numerical ranges are inclusive and combinable in any order except where it is logical that such numerical ranges are constrained to add up to 100%.

In one embodiment, the present invention generally relates to the electrodeposition of nanotwinned copper, and a copper electrolyte that is usable to produce nanotwinned copper on a substrate.

The copper electrolyte typically comprises:
a) a copper salt;
b) a source of halide ions; and
c) a suppressor, wherein the suppressor comprises a linear or branched polyhydroxyl,
   wherein the copper electrolyte also comprises one or more of:
   (i) an accelerator, wherein the accelerator comprises an organic sulfur compound; and
   (ii) a leveler, wherein the leveler comprises a polymeric quaternary nitrogen species;
   wherein the copper electroplating solution is configured to deposit nanotwinned copper by bottom up filling in a feature of a microelectronic substrate.

In a preferred embodiment, the copper salt comprises copper sulfate, Other copper salts usable in the composition include copper methane sulfonate, copper pyrophosphate, copper propanesulfonate, and other similar compounds. The concentration of copper sulfate in the electroplating solution is generally in the range of about 1-100 g/L, more preferably in the range of about 20 to about 80 g/L, most preferably within the range of about 40 to about 60 g/L.

The halide ions may act as bridges to assist adsorption of certain organic additives onto a substrate surface. Halide ions include, but are not limited to, chloride ions, bromide ions, iodide ions, and combinations thereof. In one embodiment, the halide ions comprise chloride ions. The concentration of chloride ions in the electroplating solution is generally within the range of about 1-150 mg/L, more preferably about 30-120 mg/L, most preferably about 45-75 mg/L.

In addition, the electroplating composition may contain an acid to control the conductivity of the plating bath, and suitable acids include sulfuric acid and methane sulfonic acid. In one embodiment, the acid is sulfuric acid. The concentration of acid in the electroplating solution is generally within the range of about 0 to 240 g/L, more preferably within the range of about 10 to about 180 g/L, most preferably within the range of about 80 to about 140 g/L. In one embodiment, the concentration of the acid is in the range of about 8 to about 15 g/L, more preferably about 10 g/L, which has been found to be better for via fill applications. In another embodiment, the acid concentration is higher and is in the range of about 60 to about 100 g/L.

Preferred suppressors include linear or branched polyhydroxyl compounds. Even more preferred suppressors include the reaction product of nitrogen-containing compounds with glycidol.

As described herein, in one embodiment, the suppressor comprises a linear or branched polyhydroxyl generally having a molecular weight of about 200 to about 20,000 g/mol, more preferably about 500 to about 5,000 g/mol, most preferably about 1.000 to about 3,000 g/mol. In a preferred embodiment, the linear or branched polyhydroxyl comprises poly(2,3-epoxy-1-propanol).

The inventors have also surprisingly found that reacting amine compounds with 2,3-epoxy-1-propanol can improve the properties of the nanotwinned copper. These polyhydroxyl compounds that are initiated by a core containing a nitrogen species can increase the columnar nanotwinned copper density and help initiate the nanotwinned copper more quickly than poly(2,3-epoxy-1-propanol).

Examples of these amine compounds include aminic alcohols and ammonium alcohols.

Aminic alcohols include, but are not limited to, ethanolamine, diethanolamine, triethanolamine, propanolamine, isopropanolarnine, diisopropanolamine, triisopropanolamine, N-methyl diethanolamine, N-ethyl diethanolamine, N-propyl diethanolamine, methyl monoethanolamine, N,N-dimethyl ethanolamine, N,N-diethyl ethanolamine, N-propyl monoethanolamine, N-propyl diethanolamine, N-butyl ethanolamine, N-butyl diethanolamine, N,N-dibutyl ethanolamine, hydroxy ethyl morpholine, 2-piperidino ethanol, diethanol isopropanolamine, N-(2-hydroxyethyl) pyrrolidine, 4-pyridinemethanol, 4-pyridineethanol, 4-pyridinepropanol, 2-hydroxy-4-methylpyridine, 2-hydroxymethyl-1-methylimidazole, 4-hydroxymethyl-5-methylimidazole, and combinations of the foregoing.

In addition, these amine compounds can convert to an ammonium salt by quaternizing the nitrogen, for example, by means of a methylating agent such as dimethylsulfate.

Examples of ammonium alcohols include, but are not limited to, choline chloride, b-methylcholine chloride, bis(2-hydroxyethyl)dimethylammonium chloride, tris(2-hydroxyethyl)methylammonium chloride, carnitine chloride, (2-hydroxyethyl)dimethyl(3-sulfopropyl)ammonium chloride, 1-(2-hydroxyethyl)-3-methylimidazolium chloride, and combinations of the foregoing.

In one embodiment, the concentration of the linear or branched polyhydroxyl suppressor is within the range of about 1 to about 10,000 mg/L, more preferably about 10 to about 1,000 mg/L, most preferably about 50 to about 600 mg/L.

In reacting an amine compound with 2,3-epoxy-1-propanol, the molar ratio of the amine compound to the 2,3-epoxy-1-propanol is generally in the range of about 0.01 to 0.50, more preferably in the range of 0.01 to 0.20, and more preferably in the range of 0.01 to 0.10.

Accelerators for use in the copper electroplating composition of the invention preferably comprise organic sulfur compounds, including organic sulfur salts. Suitable organic sulfur compounds include, but are not limited to bis-(3-sulfopropyl)-disulfide (SPS), 3-mercapto-1-propanesulfonic acid (MPS), 3-(benzothizolyl-2-mercapto)-propylsulfonic acid (ZPS), N,N-dimethyldithiocarbamylpropyl sulfonic acid (DPS), 3-S-isothiuronium propyl sulfonate (UPS), and (O-ethyldithiocarbonato)-S-(3-sulfopropyl)ester (OPX).

Without being bound to a particular theory, it is believed that typical higher strength accelerators such as MPS and SPS participate at the cathode surface displacing the suppressor to allow superfilling. This interaction at the plating surface disrupts the nanotwinned copper plating that is initiated by the polyhydroxyl suppressors. By utilizing weaker accelerators such as ZPS and USP, this interaction is not as strong to completely displace the suppressor and thus maintains the nanotwinned copper microstructure. In one embodiment, the accelerator comprises ZPS or UPS. In another embodiment, the accelerator consists of only ZPS and/or UPS and the copper electrolyte is at least substantially free of any higher strength accelerators such as MPS or SPS.

The concentration of the accelerator depends in part on the particular accelerator that is used in the copper electrolyte and the weaker accelerators may be used at a higher concentration than the stronger accelerators. For example, ZPS and UPS may be used in the copper electrolyte at a higher concentration than SPS. In addition, the use of a stronger accelerator such as SPS as the accelerator may also require that a high density nanotwinned copper deposit be applied as a base layer prior to a subsequent layer being deposited using a copper electrolyte that contains SPS.

A suitable concentration of UPS may be within the range of about 1 to 50 mg/L, more preferably about 10 to 25 mg/L. A suitable concentration of ZPS may be within the range of about 1 to about 50 mg/L, more preferably about 10-25 mg/L. Finally, a suitable concentration of a stronger accelerator such as SPS may be within the range of about 1 to 12 mg/L, more preferably about 6 to 10 mg/L.

Suitable leveler compounds include polymeric quaternary nitrogen species such as those described in WO2018/057590. U.S. Pat. Nos. 10,519,557, and 10,294,574, the subject matter of each of which is herein incorporated by reference in its entirety. Suitable leveler compounds also include dipyridyl levelers such as those described in U.S. Pat. No. 7,303,992 and U.S. Pat. Pub. No. 2005/0045488, the subject matter of each of which is herein incorporated by reference in its entirety.

For example, the leveler may comprise the reaction product of an aliphatic di(t-amine) with a bifunctional alkylating agent corresponding to the formula:

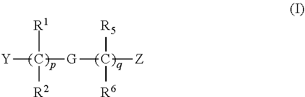

wherein: G is selected from the group consisting of a single covalent bond. —O—, O-((A)ᵣ-O)ₛ— and -((A)ᵣ-O)ₛ—; A has the structure —CR³R⁴— or —C(R³)(R⁴)C(R³³)(R³⁴)—; each of p and r is independently an integer between 1 and 6 inclusive, s is an integer between 1 and 10 inclusive, q is an integer between 0 and 6 inclusive; each of R¹, R², R³, R⁴, R⁵, R⁶ and R³⁴ is independently selected from the group consisting of hydrogen and substituted or unsubstituted aliphatic hydrocarbyl comprising 1 to 4 carbon atoms; R³³ is substituted or unsubstituted aliphatic hydrocarbyl having 1 to 4 carbon atoms, Y is a leaving group selected from the group consisting of chloride, bromide, iodide, tosyl, triflate, sulfonate, mesylate, methosulfate, fluorosulfonate, methyl tosylate, and brosylate, Z is selected from the group consisting of R³⁰ and a leaving group independently selected from the same group as Y, and R³⁰ is selected from the group consisting of aliphatic hydrocarbyl, hydroxyl, alkoxy, cyano, carboxyl, alkoxycarbonyl, and amido, and when -G- is other than a single covalent bond, q is at least one.

The leveler may also comprise an oligomer and/or polymer compound selected from the group consisting of salts comprising a cation having the structure:

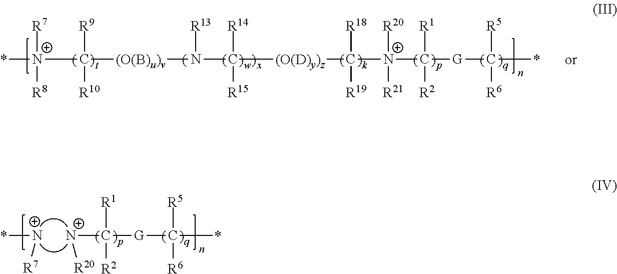

wherein: G and A are as defined above; B has the structure;

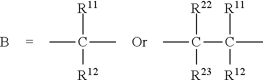

D has the structure;

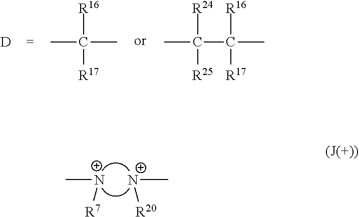

is the residue of an N,N′-dialkyl heterocyclic diamine bonded to —(CR¹R²)ₚ-G-(CR⁵R⁶)_{q}]—at the respective t-amine sites to form a di(quaternary ammonium) cationic structure;
each of p, r, t, u, w and y is an integer between 1 and 6 inclusive, each of q, v, x, k, and z is independently an integer between 0 and 6 inclusive, s is an integer between 1 and 10 inclusive, k is at least one when v or x is other than 0, q is at least one when G is other than a single covalent bond; each of R¹ to R⁶, R⁹ to R¹⁹, R²³, R²⁵ and R³⁴ is independently selected from the group consisting of hydrogen or lower alkyl comprising 1 to 4 carbon atoms, each of R⁷, R⁸, R²⁰, R²¹, R²², R²⁴ and R³³ is independently selected from the group consisting of substituted or unsubstituted aliphatic hydrocarbyl having 1 to 4 carbon atoms; and
n is between 1 and about 30.

The leveler may also comprise compounds corresponding to the formula:

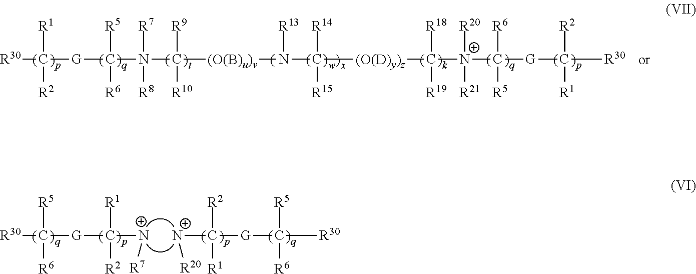

wherein: G, A, B and D are as defined above;

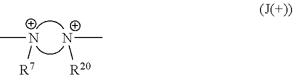

is the residue of an N,N′-dialkyl heterocyclic diamine bonded to —(CR¹R²)ₚ-G-(CR⁵R⁶)_{q}]—at the respective t-amine sites to form a di(quaternary ammonium) cationic structure; each of p, r, t, u, w and y is an integer between 1 and 6 inclusive, each of q, v, x, k, and z is independently an integer between 0 and 6 inclusive, s is an integer between 1 and 10 inclusive, k is at least one when v or x is other than 0, q is at least one when G is other than a single covalent bond; each of R¹ to R⁶, R⁹ to R¹⁹, R²³, R²⁵ and R³⁴ is independently selected from the group consisting of hydrogen or lower alkyl comprising 1 to 4 carbon atoms, each of R⁷, R⁸, R²⁰, R²¹, R²²), R²⁴ and R³³ is independently selected from the group consisting of substituted or unsubstituted aliphatic hydrocarbyl having 1 to 4 carbon atoms; and
R³⁰ is selected from the group consisting of aliphatic hydrocarbyl, hydroxyl, alkoxy, cyano, carboxyl, alkoxycarbonyl, and amido.

The leveler may also comprise a quaternized poly(epihalohydrin) comprising n repeating units corresponding to structure 1N and p repeating units corresponding to structure 1P:

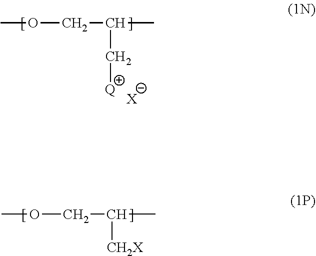

wherein Q has a structure corresponding to that which may be obtained by reacting a pendent methylene halide group of poly(epihalohydrin) with a tertiary amine selected from the group consisting of: (i) NR¹R²R³ wherein each of R¹, R² and R³ is independently selected from the group consisting of substituted or unsubstituted alkyl, substituted or unsubstituted alkenyl, substituted or unsubstituted alkynyl, substituted or unsubstituted, alicyclic, substituted or unsubstituted aralkyl, substituted or unsubstituted aryl and substituted or unsubstituted heterocyclic; (ii) an N-substituted and optionally further substituted heteroalicyclic amine wherein the N-substituent is selected from the group consisting of substituted or unsubstituted alkyl, substituted or unsubstituted alicyclic, substituted or unsubstituted aralkyl, substituted or unsubstituted aryl, and substituted or unsubstituted heterocyclic; and (iii) a substituted or unsubstituted nitrogen-containing heteroaryl compound;
n is an integer between 3 and 35, p is an integer between 0 and 25;
X is a halo substituent; and
X⁺ is a monovalent anion.

Preferably Q corresponds to structure IIA, IIB or IIC:

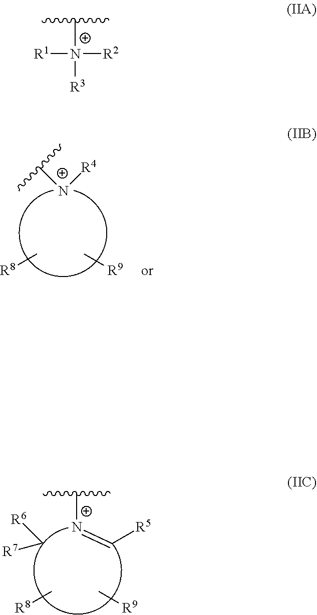

wherein: (i) structure IIB is an N-substituted heterocyclic moiety; (ii) structure TIC is a heterocyclic moiety; (iii) each of R¹, R², R³ and R⁴ is independently selected from the group consisting of substituted or unsubstituted alkyl, substituted or unsubstituted alkenyl, substituted or unsubstituted alkynyl, substituted or unsubstituted aralkyl, substituted or unsubstituted alicyclic, substituted or unsubstituted aryl, and substituted or unsubstituted heterocyclic; and (iv) each of R⁵, R⁶, R⁷, R⁸ and R⁹ is independently selected from the group consisting of hydrogen, substituted or unsubstituted alkyl, substituted or unsubstituted alkenyl, substituted or unsubstituted alkynyl, substituted or unsubstituted aralkyl, substituted or unsubstituted alicyclic, substituted or unsubstituted aryl, and substituted or unsubstituted heterocyclic. Where any of R¹ to R⁸ is substituted, the substituent preferably does not comprise an amino group.

The leveler may also comprise a substituted pyridyl compound, which may be, for example, a pyridinium compound and, in particular, a quaternized pyridinium salt. Examples of these substituted pyridyl compounds include, but are not limited to, derivatives of a vinyl pyridine, such as derivatives of 2-vinyl pyridine and derivatives of 4-vinyl pyridine, homo-polymers of vinyl pyridine, co-polymers of vinyl pyridine, quaternized salts of vinyl pyridine, and quaternized salts of these homo-polymers and co-polymers. Specific examples of such compounds include, for example, poly(4-vinyl pyridine), the reaction product of poly(4-vinyl pyridine) with dimethyl sulfate, the reaction product of 4-vinyl pyridine with 2-chloroethanol, the reaction product of 4-vinyl pyridine with benzylchloride, the reaction product of 4-vinyl pyridine with allyl chloride, the reaction product of 4-vinyl pyridine with 4-chloromethylpyridine, the reaction product of 4-vinyl pyridine with 1,3-propane sultone, the reaction product of 4-vinyl pyridine with methyl tosylate, the reaction product of 4-vinyl pyridine with chloroacetone, the reaction product of 4-vinyl pyridine with 2-methoxyethoxymethylchloride, the reaction product of 4-vinyl pyridine with 2-chloroethylether, the reaction product of 2-vinyl pyridine with methyl tosylate, the reaction product of 2-vinyl pyridine with dimethyl sulfate, the reaction product of vinyl pyridine and a water soluble initiator, poly(2-methyl-5-vinyl pyridine), and 1-methyl-4-vinylpyridinium trifluoromethyl sulfonate, among others.

Other polymeric quaternary nitrogen species can also be used as levelers in the copper electroplating composition described herein so long as they are compatible with the suppressor and accelerator and are capable of producing nanotwinned copper in features of a microelectronic substrate.

With levelers being a suppressing species along with the polyhydroxyl suppressors, the prolonged plating times of wafer level packaging applications typically drives the plating performance to be a function of leveler interaction at the plating surface. The fast kinetics of the polyhydroxyl suppressors will allow nanotwinned copper to be initiated but eventually the stronger and slower acting levelers dominate the interactions occurring at the plating surface and thus again disrupt nanotwinned copper microstructure formation. By choosing a weak leveler species, this disruption can be greatly lessened to where nanotwinned copper can be maintained, while the leveler can act as a suppressing species on the field, allowing the polyhydroxyl suppressor to act in the recess of the vias.

Thus, in one embodiment, suitable leveler species include, but are not limited to a reaction product of 4,4-dipyridyl and 2-chloroethylether. The concentration of the leveler depends in part on the particular leveler being used as well as the particular suppressor and accelerator and the process conditions. In one embodiment, the leveler is present in the copper electrolyte at a concentration within a range of about 0.5 to about 10 mg/L, more preferably about 2 to about 5 mg/L.

In a suppressor only system that can produce nanotwinned copper microstructure, higher current density (i.e., about 4 to about 20 ASD, more preferably about 6-12 ASD), is better than lower current density (i.e., in the range of about 0.5 to about 2 ASD, more preferably in the range of about 1 ASD). However, the opposite is true when superfilling copper in features of a microelectronic substrate, where lower current density (1 ASD) is better than higher current density (6 ASD).

Therefore, in one embodiment, the copper electroplating composition comprises a two or three component copper electroplating bath that is used in a step-current plating method to enable nanotwinned copper microstructure via filling. In one embodiment, a two-component copper electroplating bath can be used comprising a polyhydroxyl suppressor and leveler comprising a polymeric quaternary nitrogen species as described above. In another embodiment, a three-component copper electroplating bath can be used comprises a polyhydroxyl suppressor, an accelerator comprising an organic sulfur compound, preferably UPS, and a leveler comprising a polymeric quaternary nitrogen species. The inventors of the present invention have found that baths containing these combinations of suppressor and leveler and/or accelerator are capable of filling features such as vias when electroplated with first a high current density to generate high density nanotwinned copper, immediately followed by a lower current density step to finish the bottom-up fill.

A ramping current, where the current ramps from high to low, as opposed to step current changes, can also be applied to the 2- and 3-component copper plating bath to accomplish via filling with nanotwinned copper microstructure.

Likewise, a two-bath system can accomplish via filling with nanotwinned copper microstructure. This can be accomplished, for example, by plating high density nanotwinned copper with a copper electrolyte containing only a polyhydroxyl suppressor polyhydroxyl (i.e., the copper electrolyte is at least substantially free of any accelerator, brightener, carrier, wetter, or leveler or any compound that can function as an accelerator, brightener, carrier, wetter, or leveler), followed by plating in a separate copper electrolyte containing SPS, a polyhydroxyl suppressor, and a leveler.

Generally, the use of SPS in the copper electrolyte will deter any nanotwinned copper formation. However, when plated on a high density nanotwinned copper surface, a copper electrolyte containing up to about 10-15 mg/L ppm of SPS can be used in the composition without compromising the desired microstructure.

Thus, as described herein, in one embodiment, the copper electrolyte of the present invention may comprise:
A) about 40 to about 60 g/L copper ions;
B) about 80 to about 140 g/L sulfuric acid;
C) about 30 to about 120 mg/L chloride ions;
D) about 300 to about 500 mg/L of a linear or branched polyhydroxyl, wherein the polymer may or may not contain a nitrogen-containing species;
E) optionally, about 0.5 to about 10 mg/L of a leveler, the leveler comprising a polymer quaternary nitrogen species; and
F) optionally, about 1 to about 50 mg/L of an accelerator, the accelerator comprising an organic sulfur compound.

In another preferred embodiment, the present invention consists essentially of a copper electroplating composition capable of electrodepositing copper having a high density of nanotwinned copper, the electroplating composition consisting essentially of:
A) about 40 to about 60 g/L copper ions;
B) about 80 to about 140 g/L sulfuric acid;
C) about 30 to about 120 mg/L chloride ions;
D) about 300 to about 500 mg/L of a linear or branched polyhydroxyl wherein the polymer may or may not contain a nitrogen-containing species; and
E) about 0.5 to about 10 mg/L of a leveler, the leveler comprising a polymer quaternary nitrogen species.

In another preferred embodiment, the present invention consists essentially of a copper electroplating composition capable of electrodepositing copper having a high density of nanotwinned copper, the electroplating composition consisting essentially of:
A) about 40 to about 60 g/L copper ions;
B) about 80 to about 140 g/L sulfuric acid;
C) about 30 to about 120 mg/L chloride ions;
D) about 300 to about 500 mg/L of a linear or branched polyhydroxyl wherein the polymer may or may not contain a nitrogen-containing species;
E) about 0.5 to about 10 mg/L of a leveler, the leveler comprising a polymer quaternary nitrogen species; and
F) about 1 to about 50 mg/L of an accelerator, the accelerator comprising an organic sulfur compound.

In another embodiment, the copper electrolyte of the present invention may comprise a lower amount of sulfuric acid. For example, the copper electrolyte may comprise:
A) about 5 to about 50 g/L copper ions;
B) about 8 to about 15 g/L sulfuric acid;
C) about 30 to about 120 mg/L chloride ions;
D) about 300 to about 500 mg/L of a linear or branched polyhydroxyl, wherein the polymer may or may not contain a nitrogen-containing species;
E) optionally, about 0.5 to about 10 mg/L of a leveler, the leveler comprising a polymer quaternary nitrogen species; and
F) optionally, about 1 to about 50 mg/L of an accelerator, the accelerator comprising an organic sulfur compound.

In another preferred embodiment, the present invention consists essentially of a copper electroplating composition capable of electrodepositing copper having a high density of nanotwinned copper, the electroplating composition consisting essentially of:
A) about 5 to about 50 g/L copper ions;
B) about 8 to about 15 g/L sulfuric acid;
C) about 30 to about 120 mg/L chloride ions;
D) about 300 to about 500 mg/L of a linear or branched polyhydroxyl wherein the polymer may or may not contain a nitrogen-containing species; and
E) about 0.5 to about 10 mg/L of a leveler, the leveler comprising a polymer quaternary nitrogen species.

In another preferred embodiment, the present invention consists essentially of a copper electroplating composition capable of electrodepositing copper having a high density of nanotwinned copper, the electroplating composition consisting essentially of:
A) about 5 to about 50 g/L copper ions;
B) about 8 to about 15 g/L sulfuric acid;
C) about 30 to about 120 mg/L chloride ions;
D) about 300 to about 500 mg/L of a linear or branched polyhydroxyl wherein the polymer may or may not contain a nitrogen-containing species;
E) about 0.5 to about 10 mg/L of a leveler, the leveler comprising a polymer quaternary nitrogen species; and
F) about 1 to about 50 mg/L of an accelerator, the accelerator comprising an organic sulfur compound.

By “consisting essentially of,” what is meant is that the composition is free of any additive that would have a detrimental effect on the ability of the composition to produce a copper structure having a high density of nanotwinned copper.

The present invention also relates generally to a method of electroplating nanotwinned copper on a substrate, the method comprising the steps of:
A) providing the substrate, at least one anode, and the copper plating bath described herein;
B) contacting the substrate and the at least one anode, respectively, with the copper bath; and
C) applying an electric voltage between the surface of the workpiece and the at least one anode such that cathodic polarity is imposed upon the substrate relative to the at least one anode;
wherein a copper structure having a high density of nanotwinning is deposited on the substrate.
In some embodiments, the nanotwinned copper structures have a plurality of (111) crystal grain structures. Furthermore, to ensure the success of this method, which requires elevated temperatures and pressures, it is generally preferred to generate electroplated copper in (111) orientation with at least 80% or at least 85% or at least 90% nanotwinned columnar copper (nt-Cu) grains. While not being held to a particular theory, it is hypothesized that when the two nanotwinned copper substrates come into contact and are exposed to the necessary temperatures and pressures, the nanotwinned copper growth will extend between the boundaries of the copper substrate, forming a Cu—Cu bond that extends across the interface.

The current density is generally in the range of about 0.01 to about 50 ASD, more preferably about 0.5 to about 20 ASD, most preferably about 1 to about 10 ASD. In addition, the electroplating solution is preferably agitated, and the electroplating solution is generally mixed at about 1 to about 2,500 rpm, more preferably about 10 to about 1,200 rpm, most preferably about 50 to about 400 rpm.

The anode can be an insoluble or soluble anode. An insoluble anode is preferred. Using a soluble anode with 2,3-epoxy-1-propanol has shown to be detrimental to nt-Cu formation. However, when the suppressor is switched to a reaction product of an aminic alcohol or ammonium alcohol with glycidol, nt-Cu can be formed with both soluble and insoluble anodes.

The copper is electrodeposited for some time to plate copper to a thickness of about 0.1 to about 1,000 μm, more preferably about 0.3 to about 200 μm, most preferably about 1 to about 100 μm.

Substrates that can be plated with the copper electroplating solution described herein include printed wiring boards (PWB), printed circuit boards (PCB), and other electronic substrates that may include one or more pillars, pads, lines, and vias. In one embodiment, the substrate comprises a microelectronic substrate comprising one or more features. In one embodiment the features comprising one or more vias, trenches, lines, or other similar features that can be superfilled with copper exhibiting a high density of nanotwinning.

The presence of nanotwinned grain structures can be observed using any suitable microscopy technique, such as an electron microscopy technique. The amount of nanotwinned grain structure in the copper deposit is preferably greater than about 80%, more preferably greater than about 90% nanotwinned columnar copper grains, which is estimated based on SEM cross-sections.

As set forth in the examples below, nanotwinned copper structures may be characterized by a plurality of (111)-oriented crystal copper grains containing a majority of nanotwins. In some implementations, the plurality of (111)-oriented crystal copper grains contain a high density of nanotwins. As used herein, a “high density of nanotwins” may refer to copper structures having greater than about 80% nanotwinning, and even greater than about 90% nanotwinning as observed using suitable microscopy techniques.

The crystal orientation of the crystal copper grains may be characterized using a suitable technique such as electron backscatter diffraction (EBSD) analysis. In some implementations, crystal orientation maps may be displayed in inverse pole figure (IPF) maps. In accordance with the present invention, it is preferably that the nanotwinned copper structures contain primarily (111)-oriented grains.

### Example 1

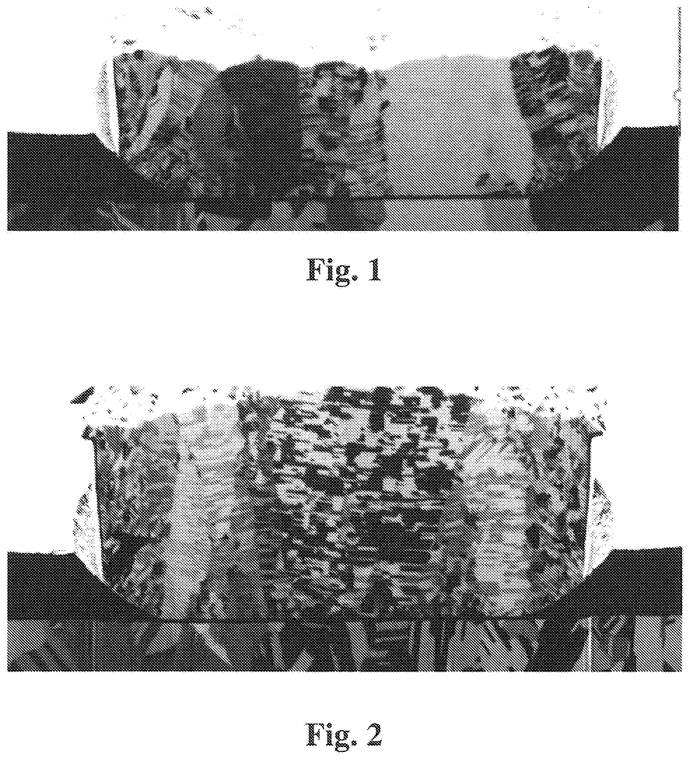

A copper electrolyte was prepared containing a solution of 50 g/L copper(II) ions, 100 g/L sulfuric acid, 50 mg/L chloride ion, 400 mg/L of an aminic polyhydroxyl suppressor, and 2 mg/L of a polyquaternary amine salt and was used to plate a via having an aspect ratio of 1:4 at a constant current of 3 ASD. The result was the desired nanotwinned copper microstructure with a dishing profile as shown in FIG. 1.

The aminic polyhydroxyl suppressor was prepared by reacting an aminic or ammonium alcohol with 2,3-epoxy-1-propanol. The general reaction procedure is as follows:

A boron trifluoride etherate (5 mmol) solution in methanol was added dropwise to a solution of 2,3-epoxy-1-propanol (2 mol) and N-methyldiethanolamine (0.2 mol) in a 1 L round bottom flask equipped with a thermometer, reflux condenser, and magnetic stirrer. The temperature was allowed to increase freely during exotherm and heated at its maximum temperature for 30 minutes. The reaction was then allowed to cool to less than 100° C., where water was added to make a 20% w/w solution that continued to stir for 4 hours. This solution was then filtered and used as-is.

### Example 2

A copper electrolyte was prepared containing a solution of 50 g/L copper(II) ions, 100 g/L sulfuric acid, 50 ng/L chloride ion, 400 mg/L of an aminic polyhydroxyl suppressor, and 2 ng/L of a polyquaternary amine salt (i.e., a dipyridyl reacted with 2-chloroether) and was used to plate a via at a constant current of 1 ASD. The result was a less than desired nanotwinned copper microstructure as compared with Example 1 but with a doming profile, indicating better via fill as shown in FIG. 2.

### Example 3

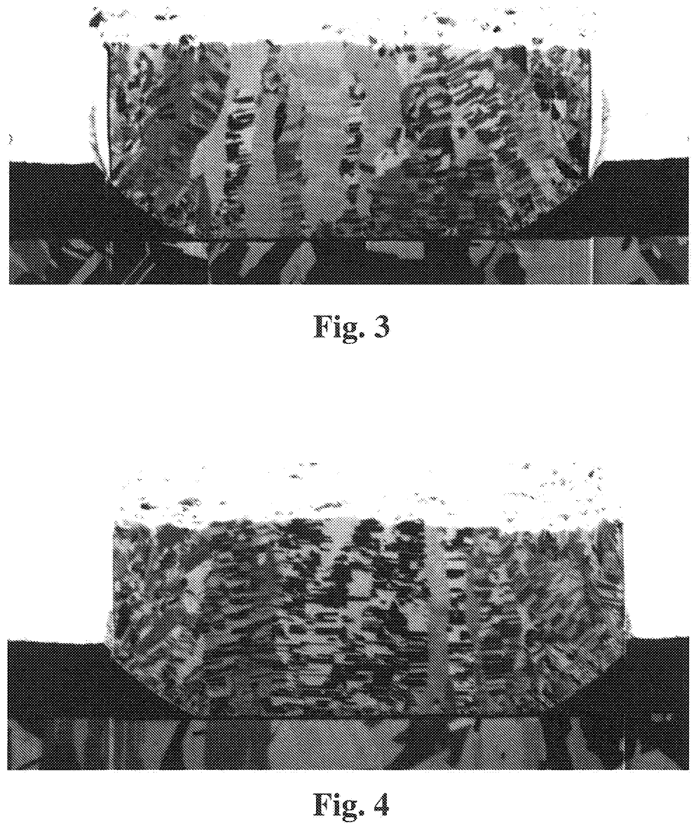

A copper electrolyte was prepared containing a solution of 50 g/L copper(II) ions, 100 g/L sulfuric acid, 50 mg/L chloride ion, 400 mg/L of an aminic polyhydroxyl suppressor, and 2 mg/L of a polyquaternary amine salt and was used to plate a via with a wave form of 3 ASD then 1 ASD (equal plating times). The result was a desired nanotwinned copper microstructure with an optimal flat profile as shown in FIG. 3.

### Example 4

A copper electrolyte was prepared containing a solution of 50 g/L copper(II) ions, 100 g/L sulfuric acid, 50 mg/L chloride ion. 400 mg/L of an aminic polyhydroxyl suppressor, 10 mg/L of UPS, and 2 mg/L of a polyquaternary amine salt and was used to plate a via with a wave form of 3 ASD then 1 ASD (equal plating times). This showed a desired nanotwinned copper microstructure with an optimal flat profile as can be seen in FIG. 4.

### Comparative Example 5

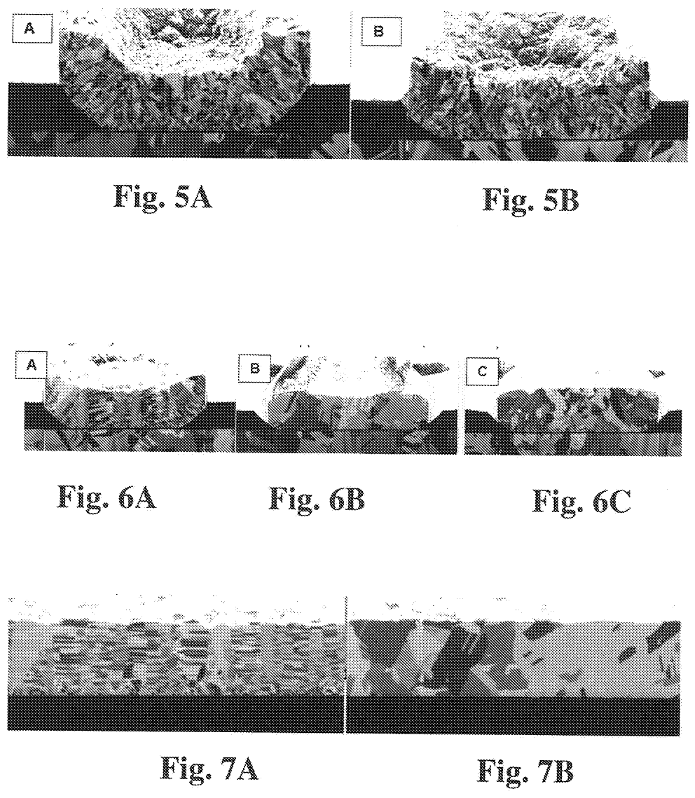

A copper electrolyte was prepared containing a solution of 50 g/L copper(II) ions, 100 g/L sulfuric acid, 50 mg/L chloride ion, 400 mg/L of an aminic polyhydroxyl suppressor, and 2 mg/L of a polyquaternary amine salt and was used to plate a via at 3 ASD. A second copper electrolyte was prepared containing 50 g/L copper(II) ions, 100 g/L sulfuric acid, 50 mg/L chloride ion, 10 mg/L UPS, 400 mg/L of a polyethylene glycol suppressor, and 2 mg/L of a Polyquaternary amine salt was used to plate a via as 3 ASD. As shown in FIGS. 5A and 5B, the use of a polyethylene glycol suppressor did not produce a nanotwinned copper microstructure.

### Comparative Example 6

A copper electrolyte was prepared containing a solution of 50 g/L copper(II) ions, 100 g/L sulfuric acid, 50 mg/L chloride ion, and (a) 400 mg/L of an aminic polyhydroxyl suppressor amine salt was used to plate a via at 3 ASD; (b) the same electrolyte with 10 mg/L SPS and 400 mg/L of an aminic polyhydroxyl suppressor was used to plate a via at 3 ASD and; (c) the same electrolyte with 10 mg/L SPS, 400 mg/L of a polyethylene glycol suppressor, and 2 mg/L of a polyquaternary amine salt and was used to plate a via at 3 ASD. It is apparent that the addition of 10 mg/L of SPS negatively affected the nanotwinned copper microstructure, but improved via fill as shown in FIGS. 6A to 6C.

### Example 7

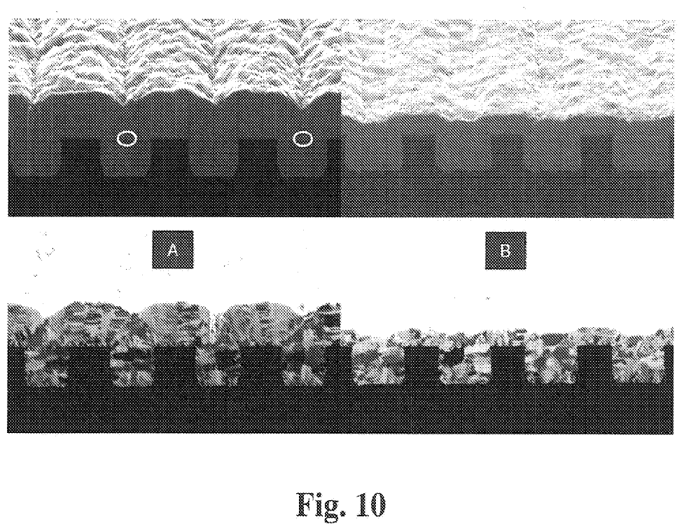

A damascene-like via was electroplated with copper electrolyte containing a solution of 40 g/L copper(II) ions, 10 g/L sulfuric acid, 50 mg/L chloride ion. The first bath containing (A) 400 mg/L of an aminic polyhydroxyl suppressor amine salt was used to plate a via at 3 ASD; (B) two different baths were prepared with the same electrolyte where first ⅓ to ½ of the via was plated with the electrolyte containing 400 mg/L of an aminic polyhydroxyl suppressor amine salt at 3ASD and the second bath containing 6 mg/L SPS, 400 mg/L of an aminic polyhydroxyl suppressor, and 1 mg/L of a dipyridyl polyquaternary amine salt was used to viafill the remaining portion of the via at 6 ASD; It is apparent that 3-component bath being plated on top of the nt-Cu microstructure from the first bath improved the via fill as shown in FIGS. 10A and 10B.

As can be seen from the Examples and Comparative Examples, the copper electrolyte described herein is capable of depositing a plated copper structure that comprises a high density of nanotwinned columnar copper grains. In addition, it can also be seen that the types and concentration of additives in the electrolyte along with the plating condition can affect both the generation of a nanotwinned copper deposit and the quality of the via fill.

FIG. 7A shows a nanotwinned copper plating deposit on a blanket surface in which the nanotwinned copper was deposited from an electrolyte containing a polyhydroxyl suppressor. As seen in FIG. 7A, the copper plated deposit exhibits a high percentage of nanotwinned copper grains aligned in a (111) orientation, in contrast. FIG. 7B shows a copper plating deposit on a blanket surface in which copper was deposited from an electrolyte containing a polyhydroxyl suppressor and 1 mg/L SPS. As seen in FIG. 7B, the nanotwinned copper microstructure is lost.

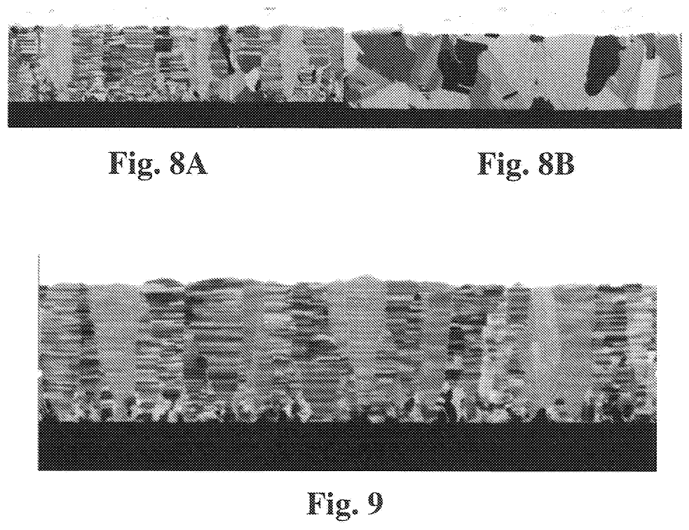

FIG. 8A shows a nanotwinned copper plating deposit on a blanket surface in which the nanotwinned copper was deposited from an electrolyte containing a polyhydroxyl suppressor and 25 mg/L UPS. As seen in FIG. 7A, the copper plated deposit exhibits a high percentage of nanotwinned copper grains aligned in a (111) orientation. In contrast, FIG. 7B shows a copper plating deposit on a blanket surface in which copper was deposited from an electrolyte containing a polyhydroxyl suppressor and 50 mgs se/L UPS. As seen in FIG. 7B, the addition of a higher amount of UPS resulted in a copper deposit in which the nanotwinned copper microstructure was lost.

FIG. 9 shows a nanotwinned copper plating deposit on a blanket surface in which the nanotwinned copper was deposited from an electrolyte containing a polyhydroxyl suppressor and 25 mg/L ZPS.

From FIGS. 7-9, it can be seen that both the type and concentration of the accelerator in the copper electrolyte can influence the formation of nanotwinned copper in the deposit.

FIG. 10A shows a nanotwinned copper plating deposit on a damascene-like via that was plated with a suppressor only bath which have a propensity to generate center voids.

Whereas, FIG. 10B shows a two-bath system, in which, a suppressor only bath was utilized to plate ⅓ of the via with nt-Cu, and the remaining ⅔ of the via is plated with an accelerator, suppressor, and leveler comprising copper plating bath. This prevents the center voids, and is also able to fill the via faster with a smaller overburden.

By the process described herein, it is possible to plate vias having a high percentage of nanotwinned copper grain growth from the bottom of the vias. This process can be used to plate vias having an aspect ratio of between 1:4 and 4:1 with a high percentage of nanotwinned copper grains where the nanotwinned copper grains grow from the bottom of the vias.

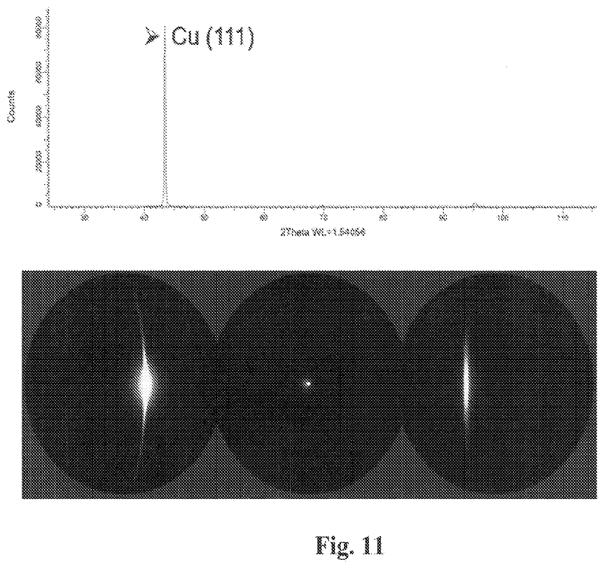

FIG. 11 shows the XRD analysis of a nt-Cu film, plated with an electrolyte containing only a suppressor, that has a high concentration of Cu (111) microstructure.

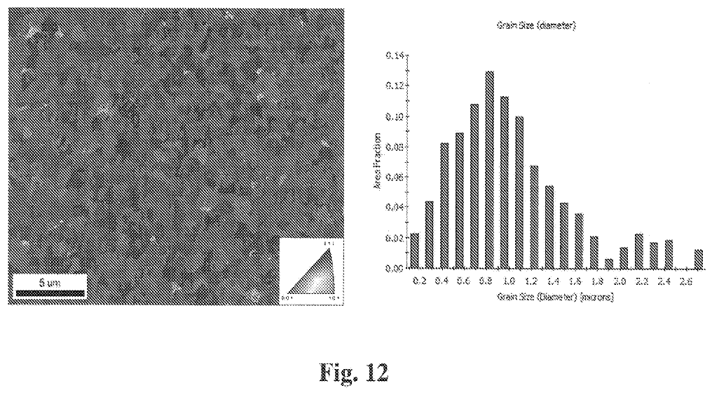

FIG. 12 the EBSD analysis of a nt-Cu film, plated with an electrolyte containing only a suppressor, that shows a majority of the copper grains are smaller than 1.0 μm.

Finally, it should also be understood that the following claims are intended to cover all of the generic and specific features of the invention described herein and all statements of the scope of the invention that, as a matter of language might fall therebetween.

What is claimed is:

1. A copper electrolyte comprising:
a) a copper salt;
b) a source of halide ions; and
c) a suppressor, wherein the suppressor comprises a linear or branched polyhydroxyl,
wherein the copper electroplating bath also comprises one or more of:
(i) an accelerator, wherein the accelerator comprises an organic sulfur compound; and
(i) a leveler, wherein the leveler comprises a polymeric quaternary nitrogen species;
wherein the copper electrolyte is capable of depositing copper, wherein the copper deposit exhibits greater than about 80% nanotwinned columnar copper grains.

2. The copper electrolyte according to claim 1, wherein the copper salt is copper sulfate.

3. The copper electrolyte according to claim 1, further comprising an acid, wherein the acid comprises sulfuric acid or methane sulfonic acid.

4. The copper electrolyte according to claim 1, wherein the linear or branched polyhydroxyl comprises poly(2,3-epoxy-1-propanol).

5. The copper electrolyte according to claim 1, wherein the linear or branched polyhydroxyl comprises a reaction product between 2,3-epoxy-1-propanol and an amine compound.

6. The copper electrolyte according to claim 1, wherein the linear or branched polyhydroxyl comprises at least one nitrogen atom.

7. The copper electrolyte according to claim 5, wherein the amine compound is selected from the group consisting of ethanolamine, diethanolamine, triethanolamine, propanolamine, isopropanolamine, diisopropanolamine, triisopropanolamine, N-methyl diethanolamine, N-ethyl diethanolamine, N-propyl diethanolamine, methyl monoethanolamine, N,N-dimethyl ethanolamine, N,N-diethyl ethanolamine, N-propyl monoethanolamine, N-propyl diethanolamine, N-butyl ethanolamine, N-butyl diethanolamine, N,N-dibutyl ethanolamine, hydroxy ethyl morpholine, 2-piperidino ethanol, diethanol isopropanolamine, N-(2-hydroxyethyl) pyrrolidine, 4-pyridinemethanol, 4-pyridineethanol, 4-pyridinepropanol, 2-hydroxy-4-methylpyridine, 2-hydroxymethyl-1-methylimidazole, 4-hydroxymethyl-5-methylimidazole, choline chloride, b-methylcholine chloride, bis(2-hydroxyethyl)dimethylammonium chloride, tris(2-hydroxyethyl)methylammonium chloride, carnitine chloride, (2-hydroxyethyl)dimethyl(3-sulfopropyl)ammonium chloride, 1-(2-hydroxyethyl)-3-methylimidazolium chloride, and combinations of the foregoing.

8. The copper electrolyte according to claim 1, wherein the accelerator is present and is selected from the group consisting of bis-(3-sulfopropyl)-disulfide, 3-mercapto-1-propanesulfonic acid, 3-(benzothizolyl-2-mercapto)-propylsulfonic acid, N,N-dimethyldithiocarbamylpropyl sulfonic acid, 3-S-isothiuronium propyl sulfonate, and (O-ethyldithiocarbonato)-S-(3-sulfopropyl)ester.

9. The copper electrolyte according to claim 8, wherein the accelerator is selected from the group consisting of 3-(benzothizolyl-2-mercapto)-propylsulfonic acid and 3-S-isothiuronium propyl sulfonate.

10. The copper electrolyte according to claim 1, wherein both the accelerator and the leveler are present in the composition.

11. The copper electrolyte according to claim 1, wherein the copper electroplating solution comprises:
a. about 40 to about 60 g/L copper ions;
b. about 80 to about 140 g/L sulfuric acid;
c. about 30 to about 120 mg/L chloride ions;
d. about 300 to about 600 mg/L linear or branched polyhydroxyl; wherein the polyhydroxyl comprises a poly(2,3-epoxy)-1-propanol directly bonded to a nitrogen-containing species.

12. The copper electrolyte according to claim 1, wherein the copper electroplating solution comprises:
a. about 5 to about 50 g/L copper ions;
b, about 8 to about 15 g/L sulfuric acid;
c. about 30 to about 120 mg/L chloride ions;
d. about 300 to about 600 mg/L linear or branched polyhydroxyl; wherein the polyhydroxyl comprises a poly(2,3-epoxy)-1-propanol directly bonded to a nitrogen-containing species.

13. The copper electroplating solution according to claim 11, further comprising:
e. about 0.5 to about 10 mg/L of the leveler, the leveler comprising a polymer quaternary nitrogen species; and
f. about 1 to about 50 mg/L of the accelerator.

14. The copper electroplating solution according to claim 11, further comprising:
e. about 0.5 to about 10 mg/L of the leveler, the leveler comprising a polymer quaternary nitrogen species.

15. The copper electroplating solution according to claim 1, wherein the copper electroplating solution is at least substantially free of any accelerator, brightener, carrier, wetter, or leveler or any compound that can function as an accelerator, brightener, carrier, wetter, or leveler.

16. A method of electrodepositing copper on a substrate, the method comprising the steps of:
a. contacting a surface of the substrate and at least one anode with the copper electrolyte of claim 1; and
b. applying an electric voltage between the surface of the substrate and the at least one anode such that cathodic polarity is imposed upon the substrate relative to the at least one anode;
wherein a copper deposit having a high density of nanotwinned columnar copper grains is deposited on the substrate.

17. The method according to claim 16, wherein the nanotwinned copper deposit is in a (111) orientation.

18. The method according to claim 16, wherein the copper deposit comprises greater than 90% nanotwinned columnar copper grains.

19. The method according to claim 16, wherein the substrate comprises one or more features selected from the group consisting of pillars, pads, lines, via and combinations of one or more of the foregoing.

20. The method according to claim 16, wherein the substrate comprises one or more vias, wherein the vias are filled with the copper deposit having the high density of nanotwinned columnar copper grains.

21. The method according to claim 20, wherein the vias are electroplated at a first current density to generate high density nanotwinned columnar copper grains and then at a second lower current density to finish bottom up fill of the micovias.

22. The method according to claim 21, wherein the first current density is in the range of about 4 to about 12 ASD and the second lower current density is in the range of about 0.5 to about 2.0 ASD.

23. A method of electrodepositing copper having a high density of nanotwinned columnar copper in vias by bottom up filling, the method comprising the steps of:
a. contacting a surface of the substrate and at least one anode with a first copper electrolyte to establish a base layer of nanotwinned copper, wherein the first copper electrolyte comprising copper ions, sulfuric acid, chloride ions, and a suppressor containing a linear or branched polyhydroxyl, wherein the first copper electrolyte is at least substantially free of any accelerator, brightener, carrier, wetter, or leveler or any compound that can function as an accelerator, brightener, carrier, wetter, or leveler; and thereafter
b. contacting a surface of the substrate and at least one anode with a second copper electrolyte to complete filling of the vias, wherein the second copper electrolyte comprising copper ions, sulfuric acid, chloride ions, a suppressor containing a linear or branched polyhydroxyl, an accelerator comprising an organic sulfur compound, and optionally, a leveler;
wherein an electric voltage is applied between the surface of the substrate and the at least one anode such that cathodic polarity is imposed upon the substrate relative to the at least one anode during the steps of contacting the surface of the substrate with the first copper electrolyte and the second copper electrolyte;
wherein the copper deposited in the vias exhibits the high density of nanotwinned columnar copper grains.

24. The method according to claim 23, wherein the copper deposit exhibits greater than about 80% nanotwinned columnar copper grains.

25. The method according to claim 23, wherein the nanotwinned copper deposit is in a (111) orientation.

26. A substrate comprising one or more vias, wherein the one or more vias are filled with a nanotwinned copper plated deposit,
wherein at least one of the one or more vias has an aspect ratio of between 1:4 and 4:1 and is plated with the copper electrolyte of claim 1, and
wherein the plated deposit exhibits a high percentage of nanotwinned copper grains, where the nanotwinned copper grains grow from the bottom of the via.

27. The substrate according to claim 26, wherein the copper deposit exhibits greater than about 80% nanotwinned columnar copper grains.
